(19) United States
(12) Patent Application Publication
(10) Pub. No.: US 2024/0343943 A1
(43) Pub. Date: Oct. 17, 2024

(54) POLISHING COMPOSITION, POLISHING COMPOSITION PRODUCTION METHOD, POLISHING METHOD, AND SEMICONDUCTOR SUBSTRATE PRODUCTION METHOD

(71) Applicant: FUJIMI INCORPORATED, Aichi (JP)

(72) Inventor: Ryota Mae, Aichi (JP)

(73) Assignee: FUJIMI INCORPORATED, Aichi (JP)

(21) Appl. No.: 18/684,991

(22) PCT Filed: Jul. 29, 2022
(86) PCT No.: PCT/JP2022/029299

§ 371 Date: Feb. 20, 2024

(30) Foreign Application Priority Data
Aug. 20, 2021 (JP) 2021-134972

(51) Int. Cl. C09G 1/02; H01L 21/3105

(52) U.S. Cl. CPC C09G 1/02; H01L 21/31053

(57) ABSTRACT

There are provided a polishing composition capable of increasing the polishing removal rate of silicon nitride, a polishing composition production method, a polishing method, and a semiconductor substrate production method. The polishing composition contains abrasives having a zeta potential of −5 mV or less and a cationic surfactant.

### TECHNICAL FIELD

The present invention relates to a polishing composition, a polishing composition production method, a polishing method, and a semiconductor substrate production method.

### BACKGROUND ART

In recent years, with the multilayer wiring on the surface of a semiconductor substrate, a so-called chemical mechanical polishing (CMP) technology of polishing and flattening a semiconductor substrate is utilized in producing a semiconductor device. The CMP is a method for flattening the surfaces of objects to be polished (polishing targets), such as a semiconductor substrate, using a polishing composition (slurry) containing abrasives of silica, alumina, and ceria, an anticorrosive agent, a surfactant, and the like. The objects to be polished (polishing targets) are wiring and plugs containing silicon, polysilicon, silicon oxide, silicon nitride, metal, and the like.

Various proposals have been made so far with respect to the polishing composition used in polishing the semiconductor substrate by the CMP. For example, PTL 1 describes a “polishing composition used for polishing objects to be polished containing a silicon oxide film, the polishing composition containing abrasives, a compound having a logarithmic value of the partition coefficient (Log P) of 1.0 or more, and a dispersion medium and having a pH less than 7.

### CITATION LIST

### Patent Literature

PTL 1: JP 2020-37669 A

### SUMMARY

### Technical Problem

With respect to the polishing removal rate of a silicon nitride film, conventional polishing compositions have not always satisfied the requirements of users. The enhancement of the polishing removal rate of the silicon nitride film has been desired.

The present invention has been made in view of the circumstances. It is an object of the present invention to provide a polishing composition capable of increasing the polishing removal rate of silicon nitride, a polishing composition production method, a polishing method, and a semiconductor substrate production method.

### Solution to Problem

The present inventors have advanced extensive studies in view of the above-described problem. As a result, the present inventors have found that the polishing removal rate of silicon nitride increases by using a polishing composition containing abrasives having a zeta potential of −5 mV or less and a cationic surfactant, and thus have accomplished the invention.

### Advantageous Effects of Invention

The present invention can provide a polishing composition capable of increasing (enhancing) the polishing removal rate of silicon nitride, a polishing composition production method, a polishing method, and a semiconductor substrate production method.

### DESCRIPTION OF EMBODIMENTS

Embodiments of the present invention will now be described in detail. A polishing composition according to the embodiment of the present invention (hereinafter, this embodiment) is a polishing composition containing abrasives having a zeta potential of −5 mV or less and a cationic surfactant.

The polishing composition may be applicable to the use for polishing objects to be polished, such as simple-substance silicon, silicon compounds, and metals, e.g., use for polishing surfaces containing simple-substance silicon, polysilicon, silicon compounds, metals, and the like which are semiconductor substrates in a semiconductor device production process, and is suitable for use for polishing a silicon nitride film on a silicon oxide film. For example, the polishing composition is suitable for use for polishing a silicon nitride film on a silicon oxide film formed using tetraethoxysilane (Si(OC₂H₅)₄). When the polishing is performed using the polishing composition, the silicon nitride film can be polished with a high polishing removal rate while the polishing removal rate of the silicon oxide film is suppressed in some cases. Hereinafter, the polishing composition according to this embodiment is described in detail.

### <Abrasives>

The polishing composition according to this embodiment contains abrasives having the zeta potential of −5 mV or less. The abrasives having the zeta potential of −5 mV or less may be anion-modified silica. The silica may be colloidal silica. More specifically, the abrasives may be anion-modified colloidal silica.

### (Zeta Potential)

The abrasives used for the polishing composition according to this embodiment are preferably those having a pH of 7 or less and the zeta potential of −5 mV or less. The zeta potential of the abrasives is preferably −10 mV or less and more preferably −13 mV or less from the viewpoint of the enhancement of the polishing removal rate. The zeta potential of the abrasives is preferably −60 mV or more, more preferably −50 mV or more, and still more preferably −30 mV or more from the viewpoint of reducing defects. Due to the fact that the colloidal silica has the zeta potential in such ranges, defects, such as scratches, which may be generated on the surface of an object to be polished after the polishing using the polishing composition can be suppressed while the polishing removal rate for silicon nitride is enhanced.

Herein, the zeta potential of the abrasives in the polishing composition is calculated by subjecting the polishing composition to ELS-Z2 manufactured by Otsuka Electronics Co. Ltd., performing measurement by a laser doppler method (electrophoretic light scattering measurement method) using a flow cell at a measurement temperature of 25° C., and analyzing the obtained data using Smoluchowski Formula.

### (Production Method)

Examples of a colloidal silica production method include a soda silicate method and a sol-gel method. Any colloidal silica produced by any production method is suitably used as the colloidal silica of the present invention. However, from the viewpoint of reducing metal impurities, colloidal silica produced by the sol-gel method is preferable. The colloidal silica produced by the sol-gel method is preferable due to a small content of metal impurities or corrosive ions, such as chloride ions, diffusible in semiconductors. The production of the colloidal silica by the sol-gel method can be performed using conventionally known methods. Specifically, the colloidal silica can be obtained by performing a hydrolysis/condensation reaction using a hydrolyzable silicon compound (e.g., alkoxysilane or derivatives thereof) as a raw material.

### (Surface Modification)

The type of the colloidal silica to be used is not particularly limited, and surface-modified colloidal silica is usable, for example. The surface modification of the colloidal silica can be performed by chemically bonding functional groups of organic acids to the surface of the colloidal silica, i.e., immobilization of organic acid, for example. Alternatively, the surface modification of the colloidal silica can be performed by doping the surfaces of silica particles with metal, such as aluminum, titanium, or zirconium, or mixtures of oxides of the metals and the colloidal silica.

In this embodiment, the colloidal silica contained in the polishing composition is colloidal silica having the surface on which organic acid is immobilized, for example. The colloidal silica having the surface on which organic acid is immobilized tends to have a larger absolute value of the zeta potential in the polishing composition than that of normal colloidal silica having the surface on which organic acid is not immobilized. Therefore, the zeta potential of the colloidal silica in the polishing composition is easily set in the range of −5 mV or less.

The zeta potential of the colloidal silica can be controlled in a desired range by using acids described later as a pH adjuster, for example.

Examples of the colloidal silica having the surface on which organic acid is immobilized include colloidal silica having the surface on which organic acids, such as carboxylic acid groups, sulfonic acid groups, phosphonic acid groups, and aluminate groups, are immobilized. Among the above, the colloidal silica having the surface on which sulfonic acid or carboxylic acid is immobilized is preferable and the colloidal silica having the surface on which sulfonic acid is immobilized is more preferable from the viewpoint of ease of production.

The immobilization of the organic acids to the surface of the colloidal silica is not achieved simply by the coexistence of the colloidal silica and the organic acids. For example, when sulfonic acid which is one species of the organic acids is immobilized to the colloidal silica, the immobilization can be performed by the method described in “Sulfonic acid-functionalized silica through of thiol groups”, Chem. Commun., 246-247 (2003), for example. Specifically, the colloidal silica having the surface on which sulfonic acid is immobilized (sulfonic acid-modified colloidal silica) can be obtained by coupling a silane coupling agent having a thiol group, such as 3-mercaptopropyltrimethoxysilane, to the colloidal silica, and then oxidizing the thiol group with hydrogen peroxide.

Alternatively, when carboxylic acid which is one species of the organic acids is immobilized to the colloidal silica, the immobilization can be performed by the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000), for example. Specifically, the colloidal silica having the surface on which carboxylic acid is immobilized (carboxylic acid-modified colloidal silica) can be obtained by coupling a silane coupling agent containing photoreactive 2-nitrobenzyl ester to the colloidal silica, followed by light irradiation.

### (Average Primary Particle Diameter)

The lower limit of the average primary particle diameter of the abrasives in the polishing composition of the present invention is preferably 1 nm or more, more preferably 5 nm or more, and still more preferably 7 nm or more. The upper limit of the average primary particle diameter of the colloidal silica in the polishing composition of the present invention is preferably 100 nm or less, more preferably 50 nm or less, still more preferably 30 nm or less, and particularly preferably 20 nm or less. In the ranges above, defects, such as scratches, which may be generated on the surface of the object to be polished after the polishing using the polishing composition can be suppressed. The average primary particle diameter of the colloidal silica is calculated based on the specific surface area of the colloidal silica measured by the BET method, for example.

### (Average Secondary Particle Diameter)

The lower limit of the average secondary particle diameter of the abrasives in the polishing composition of the present invention is preferably 2 nm or more, more preferably 10 nm or more, still more preferably 15 nm or more, and particularly preferably 20 nm or more. The upper limit of the average secondary particle diameter of the colloidal silica in the polishing composition of the present invention is preferably 200 nm or less, more preferably 100 nm or less, still more preferably 80 nm or less, and particularly preferably 40 nm or less. In the ranges above, defects, such as scratches, which may be generated on the surface of the object to be polished after the polishing using the polishing composition can be suppressed.

The secondary particles refer to particles formed by the association of the abrasives (primary particles) in the polishing composition. The average secondary particle diameter of the abrasives can be measured by dynamic light scattering typified by laser diffraction scattering, for example.

### (Average Degree of Association)

The average degree of association of the abrasives is preferably 5.0 or less, more preferably 4.0 or less, and still more preferably 3.0 or less. With a decrease in the average degree of association of the colloidal silica, it is easier to obtain a polished surface with fewer surface defects by polishing the object to be polished using the polishing composition. The average degree of association of the abrasives is preferably 1.0 or more and more preferably 1.5 or more. An increase in the average degree of association of the abrasives is advantageous for enhancing the removal rate of the object to be polished with the polishing composition. The average degree of association of the abrasives is obtained by dividing the value of the average secondary particle diameter of the abrasives by the value of the average primary particle diameter of the abrasives.

### (Shape)

In the present invention, the shape of the abrasives is not particularly restricted and may be either a spherical shape or a non-spherical shape, and a non-spherical shape is preferable. Specific examples of the non-spherical shape include, but are not particularly restricted to, various shapes, such as polygonal columnar shapes, such as a triangular column or a square column, a cylindrical shape, a barrel shape in which a center portion of a cylinder is bulged more than an edge portion of the cylinder, a donut shape having a penetrating disk center portion, a plate shape, a cocoon shape having a neck in a center portion (e.g., two spheres are joined to each other and a joint portion of the two spheres is thin and narrow like a neck), an associated spherical shape in which a plurality of particles is united, a confetti-like shape having a plurality of bumps in the surface, a rugby-ball shape, and a bead-like shape.

### (Content)

The lower limit of the content of the abrasives is preferably 0.1 mass % or more, more preferably 0.3 mass % or more, and still more preferably 0.5 mass % or more based on the polishing composition. The upper limit of the content of the abrasives is preferably 20 mass % or less, more preferably 10 mass % or less, and still more preferably 2 mass % or less based on the polishing composition. In the ranges above, the polishing removal rate can be further enhanced. When the polishing composition contains two or more types of abrasives, the content of the abrasives means the total amount of the abrasives.

(Other Particles Other than Silica)

The polishing composition according to this embodiment may contain silica having the zeta potential of −5 mV or less (e.g., anion-modified colloidal silica) and other abrasives other than silica as the abrasives. Alternatively, the polishing composition may contain abrasives having the zeta potential of −5 mV or less other than silica. Examples of the other abrasives include metal oxide particles, such as alumina particles, zirconia particles, and titania particles, for example.

### <Liquid Medium>

The polishing composition according to this embodiment can contain a liquid medium. The liquid medium functions as a dispersion medium or a solvent for dispersing or dissolving, respectively, components (e.g., additives, such as anion-modified colloidal silica, cationic surfactants, and pH adjusters) of the polishing composition. Examples of the liquid medium include water and organic solvents. One type of the liquid media can be used alone or two or more types thereof can be used as a mixture, and the liquid media preferably contain water. However, from the viewpoint of preventing the inhibition of the action of each component, water containing as little impurities as possible is preferably used. Specifically, pure water or ultrapure water obtained by removing impurity ions with an ion exchange resin, and then removing contaminants through a filter or distilled water is preferable.

### <pH Adjuster>

The polishing composition according to this embodiment has a pH value of preferably 7 or less, more preferably 5 or less, still more preferably 4 or less, and particularly preferably 3 or less. The pH value is preferably 0.5 or more, more preferably 1 or more, and still more preferably 1.8 or more. When the polishing composition is acidic, the polishing removal rate of the silicon nitride film can be enhanced. To achieve the pH values described above, the polishing composition may contain a pH adjuster.

The pH value of the polishing composition can be adjusted by adding the pH adjuster. The pH adjuster to be used may be any of acids and alkalis or may be any of inorganic compounds and organic compounds.

Specific examples of the acids as the pH adjuster include inorganic acids or organic acids, such as carboxylic acids and organic sulfuric acids. Specific examples of the inorganic acids include sulfuric acid, nitric acid, boric acid, carbonic acid, hypophosphorous acid, phosphorous acid, phosphoric acid, and the like. As the pH adjuster, the inorganic acids are preferably used. Among the inorganic acids, nitric acid is more preferable. The organic acids include carboxylic acids and organic sulfuric acids. Specific examples of the carboxylic acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, and the like. Specific examples of the organic sulfuric acids include methanesulfonic acid, ethanesulfonic acid, isethionic acid, camphor-sulfonic acid, and the like. One type of the acids may be used alone or two or more types thereof may be used in combination. These acids may be contained as the pH adjuster in the polishing composition, may be contained as an additive for enhancing the polishing removal rate, or may be contained as both the pH adjuster and the additive in combination.

Specific examples of the alkalis as the pH adjuster include alkali metal hydroxides or salts thereof, alkaline earth metal hydroxides or salts thereof, quaternary ammonium hydroxides or salts thereof, ammonia, amines, and the like. Specific examples of the alkali metals include potassium, sodium, and the like. Specific examples of the alkaline earth metals include calcium, strontium, and the like. Specific examples of the salts include carbonates, hydrogen carbonates, sulfates, acetates, and the like. Specific examples of the quaternary ammonium include tetramethylammonium, tetraethylammonium, tetrabutylammonium, and the like.

Quaternary ammonium hydroxide compounds include quaternary ammonium hydroxides or salts thereof. Specific examples include tetramethylammonium hydroxide, tetraethylammonium hydroxide, tetrabutylammonium hydroxide, and the like. Specific examples of the amines include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, N-methylpiperazine, guanidine, and the like.

One type of the alkalis may be used alone or two or more types thereof may be used in combination. Among the alkalis, ammonia, ammonium salts, alkali metal hydroxides, alkali metal salts, quaternary ammonium hydroxide compounds, and amines are preferable, and ammonia, potassium compounds, sodium hydroxides, quaternary ammonium hydroxide compounds, ammonium hydrogen carbonates, ammonium carbonates, sodium hydrogen carbonates, and sodium carbonates are more preferable. The polishing composition more preferably contains potassium compounds as the alkali from the viewpoint of preventing metal contamination. Examples of the potassium compounds include potassium hydroxides or potassium salts. Specific examples include potassium hydroxide, potassium carbonate, potassium hydrogen carbonate, potassium sulfate, potassium acetate, potassium chloride, and the like.

### <Surfactant>

The polishing composition according to this embodiment contains the cationic surfactant. The cationic surfactant has an action of imparting hydrophilicity to the polished surface of the object to be polished after polishing, and therefore the cleaning efficiency of the object to be polished after polishing can be improved and the adhesion of dirt and the like can be suppressed.

Specific examples of the cationic surfactant include amine oxides, alkyltrimethylammonium salts, alkyldimethylammonium salts, alkylbenzyldimethylammonium salts, and alkylamine salts. Among the above, amine oxides are preferable.

Specific examples of the amine oxides include alkyl amine oxides in which R1 in Formula (1) has 3 to 15 carbon atoms (N,N-dimethyldecylamine-N-oxide, N,N-dimethyldodecylamine-N-oxide, coconut oil alkyl dimethyl amine oxide, dodecyl dimethyl amine oxide, decyl dimethyl amine oxide, tetradecyl dimethyl amine oxide, N,N-dimethylnonylamine-N-oxide, and the like), pyridine-N-oxide, N-methylmorpholine-N-oxide, octyl dimethyl amine oxide, and trimethylamine-N-oxide. Among the above, alkyl amine oxides in which R1 in Formula (1) has 8 to 12 carbon atoms (N,N-dimethyldecylamine-N-oxide, N,N-dimethyldodecylamine-N-oxide) are preferable.

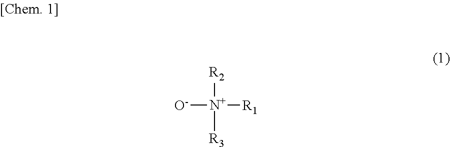

One type of the surfactants may be used alone or two or more types thereof may be used in combination.

When the content of the surfactant in the overall polishing composition is larger, the cleaning efficiency of the object to be polished after polishing is enhanced. Therefore, the content of the cationic surfactant in the overall polishing composition is preferably 0.01 g/L or more, more preferably 0.05 g/L or more, and still more preferably 0.5 g/L or more.

When the content of the surfactant in the overall polishing composition is smaller, the residual amount of the surfactant on the polished surface of the object to be polished after polishing is reduced, and the cleaning efficiency is further enhanced. Therefore, the content of the cationic surfactant in the overall polishing composition is preferably 10 g/L or less, more preferably 5.0 g/L or less, and still more preferably 2.0 g/L or less.

### <Defect Reducing Agent>

The polishing composition according to this embodiment may contain a defect reducing agent. The addition of the defect reducing agent to the polishing composition enables the suppression of defects, such as scratches, which may be generated on the surface of the object to be polished after the polishing using the polishing composition. The defect reducing agent is preferably a water-soluble polymer.

### <Water-Soluble Polymer>

As the water-soluble polymer, nonionic polymers, such as polyvinyl alcohol (PVA), polyvinylpyrrolidone (PVP), polyethylene glycol (PEG), polypropylene glycol, polybutylene glycol, a copolymer of oxyethylene (EO) and oxypropylene (PO), methyl cellulose, hydroxyethyl cellulose, dextrin, and pullulan, anionic polymers, such as polyacrylic acid, carboxymethylcellulose, polyvinylsulfonic acid, polyanethol sulfonic acid, and polystyrene sulfonic acid, and cationic polymers, such as polyethyleneimine, polyvinylimidazole, and polyallylamine, are all usable. One type of the water-soluble polymers may be used alone or two or more types thereof may be used in combination. Among the water-soluble polymers, polyvinyl alcohol (PVA), polyvinylpyrrolidone (PVP), polyacrylic acid, and polystyrene sulfonic acid are preferable, polyacrylic acid and polystyrene sulfonic acid are more preferable, and polystyrene sulfonic acid is particularly preferable from the viewpoint that defects, such as scratches, which may be generated on the surface of the object to be polished can be suppressed.

The weight average molecular weight of the water-soluble polymer is preferably 1,000 or more. When the weight average molecular weight is 1,000 or more, the contaminant removal effect is further increased. This is assumed to be because the covering property when the polished object-to-be-polished or contaminants is/are covered is further improved, and the action of removing contaminants from the surface of an object to be cleaned or the action of suppressing the re-adhesion of contaminants to the surface of the polished object-to-be-polished is further enhanced. From the same viewpoint, the weight average molecular weight is more preferably 2,000 or more and still more preferably 4,000 or more.

The weight average molecular weight of the water-soluble polymer is preferably 100,000 or less. When the weight average molecular weight is 100,000 or less, the contaminant removal effect is further increased. This is assumed to be because the removability of sulfonic acid group-containing polymers after a cleaning step is further improved. From the same viewpoint, the weight average molecular weight is more preferably 80,000 or less and still more preferably 50,000 or less.

The weight average molecular weight can be measured by gel permeation chromatography (GPC), and specifically can be measured by the method described in Examples.

The content (concentration) of the water-soluble polymer is preferably 0.001 g/L or more based on the total amount of a surface treatment composition. When the content of the water-soluble polymer is 0.001 g/L or more, the contaminant removal effect is further enhanced. This is assumed to be because, when the water-soluble polymer covers the polished object-to-be-polished and contaminants, a larger area is covered. Thus, particularly the contaminants are likely to form micelles, and therefore the contaminant removal effect by the dissolution/dispersion of the micelles is enhanced. From the same viewpoint, the content (concentration) of the water-soluble polymer is more preferably 0.003 g/L or more and still more preferably 0.005 g/L or more based on the total amount of the surface treatment composition. The content (concentration) of the water-soluble polymer is preferably 0.5 g/L or less based on the total amount of the surface treatment composition. When the content (concentration) of the water-soluble polymer is 0.5 g/L or less, the contaminant removal effect is further increased. This is assumed to be because the removability of the water-soluble polymer itself after the cleaning step is improved. From the same viewpoint, the content of the water-soluble polymer is more preferably 0.2 g/L or less and still more preferably 0.1 g/L or less based on the total amount of the surface treatment composition.

### <Oxidant>

The polishing composition according to this embodiment may contain an oxidant. When the object to be polished contains silicon, e.g., Poly-Si (polycrystalline silicon), the polishing removal rate can be adjusted by adding the oxidant to the polishing composition. More specifically, by selecting the type of the oxidant to be added to the polishing composition, the polishing removal rate of Poly-Si can be increased or reduced. Specific examples of the oxidant include hydrogen peroxide, peracetic acid, percarbonate, urea peroxide, perchloric acid, persulfate, and the like. Specific examples of the persulfate include sodium persulfate, potassium persulfate, ammonium persulfate, and the like. One type of the oxidants may be used alone or two or more types thereof may be used in combination. Among the oxidants, persulfate and hydrogen peroxide are preferable, and hydrogen peroxide is particularly preferable.

When the content of the oxidant in the overall polishing composition is larger, the polishing removal rate of the object to be polished with the polishing composition is more easily changed. Thus, the content of the oxidant in the overall polishing composition is preferably 0.01 mass % or more, more preferably 0.05 mass % or more, and still more preferably 0.1 mass % or more. When the content of the oxidant in the overall polishing composition is smaller, the material cost of the polishing composition can be further suppressed. Further, a load of the disposal of the polishing composition after the polishing composition is used for polishing, i.e., waste fluid disposal, can be reduced. Further, excessive oxidation of the surface of the object to be polished with the oxidant is less likely to occur. Thus, the content of the oxidant in the overall polishing composition is preferably 10 mass % or less, more preferably 5 mass % or less, and still more preferably 3 mass % or less.

### <Complexing Agent>

The polishing composition according to this embodiment may contain a complexing agent. The addition of the complexing agent to the polishing composition can enhance the polishing removal rate of the object to be polished with the polishing composition. The complexing agent has the action of chemically etching the surface of the object to be polished.

The lower limit of the content of the complexing agent in the overall polishing composition is not particularly limited because the effects are exhibited even in small amounts. However, when the content of the complexing agent is larger, the polishing removal rate of the object to be polished with the polishing composition is further enhanced. Therefore, the content of the complexing agent in the overall polishing composition is preferably 0.001 g/L or more, more preferably 0.01 g/L or more, and still more preferably 1 g/L or more. When the content of the complexing agent in the overall polishing composition is smaller, the object to be polished is less likely to dissolve and is enhanced in the level difference elimination property. Thus, the content of the complexing agent in the overall polishing composition is preferably 20 g/L or less, more preferably 15 g/L or less, and still more preferably 10 g/L or less.

### <Antifungal Agent, Preservative>

The polishing composition may contain an antifungal agent and a preservative. Specific examples of the antifungal agent and the preservative include isothiazoline preservatives (e.g., 2-methyl-4-isothiazolin-3-one, 5-chloro-2-methyl-4-isothiazolin-3-one), peroxybenzoates, and phenoxyethanol. One type of the antifungal agents and the preservatives may be used alone or two or more types thereof may be used in combination.

### <Polishing Composition Production Method>

A polishing composition production method according to this embodiment includes a step of mixing the abrasives having the zeta potential of −5 mV or less, the cationic surfactant, and the liquid medium. For example, the polishing composition according to this embodiment can be produced by stirring and mixing the anion-modified colloidal silica as the abrasives, the amine oxide as the cationic surfactant, and, as required, the various additives (e.g., pH adjuster, water-soluble polymer, oxidant, complexing agent, antifungal agent, preservative, and the like) in the liquid medium, such as water. The temperature in the mixing is not particularly limited, and is preferably 10° C. or more and 40° C. or less, for example, and heating may be performed to enhance the dissolution rate. The mixing time is also not particularly limited.

### <Objects to be Polished>

The polishing composition according to this embodiment can enhance the polishing removal rate of the silicon nitride film. Therefore, the objects to be polished are preferably silicon nitride films. The type of the objects to be polished is not particularly limited to the silicon nitride film, and simple-substance silicon, silicon compounds other than the silicon nitride film, metals, and the like may acceptable. Examples of the simple-substance silicon include monocrystalline silicon, polysilicon, amorphous silicon, and the like, for example. Examples of the silicon compounds include silicon dioxide, silicon carbide, and the like, for example. The silicon dioxide may be a film formed using tetraethoxysilane ((Si(OC₂H₅)₄). Silicon compound films include low dielectric constant films having a relative dielectric constant of 3 or less. Examples of the metals include tungsten, copper, aluminum, hafnium, cobalt, nickel, titanium, tantalum, gold, silver, platinum, palladium, rhodium, ruthenium, iridium, osmium, and the like, for example. The metals may be contained in the form of alloys or metal compounds.

### <Polishing Method>

The configuration of a polishing device is not particularly limited. For example, common polishing devices are usable which include a holder holding a substrate or the like having the object to be polished, a drive unit, such as a motor having a changeable rotation speed, and a polishing platen to which a polishing pad can be attached. As the polishing pad, common non-woven fabrics, polyurethane, porous fluororesin, and the like are usable without being particularly restricted. As the polishing pad, those subjected to grooving such that a liquid polishing composition stays are usable.

The polishing conditions are not particularly restricted, and the rotation speed of the polishing platen is preferably 10 rpm (0.17 s⁻¹) or more and 500 rpm (8.3 s⁻¹) or less, for example. The pressure (polishing pressure) applied to the substrate having the object to be polished is preferably 0.5 psi (3.4 kPa) or more and 10 psi (68.9 kPa) or less. A method for supplying the polishing composition to the polishing pad is also not particularly restricted, and a method for continuously supplying the polishing composition with a pump or the like is adopted. The supply amount is not restricted, and the surface of the polishing pad is preferably always covered with the polishing composition according to one aspect of the present invention.

The polishing composition according to this embodiment may be a one-component type or a multi-component type including a two-component type. The polishing composition may also be prepared by diluting a liquid concentrate of the polishing composition to 1.5 to 3-fold or more, for example, using a diluent, such as water.

After the polishing, the substrate is cleaned with running water, for example, and dried by removing water droplets adhering onto the substrate with a spin dryer or the like, thereby giving the substrate having a layer containing a silicon-containing material, for example. Thus, the polishing composition according to this embodiment is usable in application of polishing the substrate. The surface of the object to be polished, such as a silicon nitride film, provided on the semiconductor substrate (one example of the substrate) is polished using the polishing composition according to this embodiment, so that the polished semiconductor substrate can be produced. Examples of the semiconductor substrate include silicon wafers having layers containing simple-substance silicon, silicon compounds, such as a silicon nitride film, metals, and the like, for example.

### <Semiconductor Substrate Production Method>

A semiconductor substrate production method according to this embodiment includes a step of polishing the surface of a semiconductor substrate using the polishing composition described above. A polishing method in this step is as described in the <Polishing method> section above, for example.

### EXAMPLES

The present invention is described in more detail with reference to Examples and Comparative Examples described below. However, the technical scope of the present invention is not restricted to only Examples described below. Examples described below can be variously altered or modified, and such altered or modified aspects may also be included in the present invention.

### <Polishing Composition Preparation Method>

### Examples 1 to 11

As shown in Table 1 below, mixture liquids were prepared by stirring and mixing abrasives having the zeta potential of −5 mV or less, cationic surfactants, and water, which is the liquid medium. A pH adjuster was added to each created mixture liquid, thereby producing polishing compositions of Examples 1 to 6. In Table 1, “-” indicates that the component was not used or indicates having no units.

TABLE 1

| | Abrasives | | | | Cationic surfactant | | |
|---|---|---|---|---|---|---|---|
| | Concen- | Primary | Secondary | | | Concen- | Defect reducing |
| | tration | particle | particle | Zeta | | tration | agent |
| | wt % | diameter | diameter | potential/mV | Compound | g/L | Compound |
| Ex. 1 | 1 | 12 | 30 | −45 | N,N- | 1 | — |
| | | | | | dimethyldecylamine- | | |
| | | | | | N-oxide | | |
| Ex. 2 | 1 | 12 | 30 | −45 | N,N- | 1 | — |
| | | | | | dimethyldecylamine- | | |
| | | | | | N-oxide | | |
| Ex. 3 | 1 | 12 | 30 | −45 | N,N- | 0.1 | — |
| | | | | | dimethyldecylamine- | | |
| | | | | | N-oxide | | |
| Ex. 4 | 1 | 12 | 30 | −45 | N,N- | 1 | — |
| | | | | | dimethyldodecylamine- | | |
| | | | | | N-oxide | | |
| Comp. | 1 | 12 | 30 | −45 | — | — | — |
| Ex. 1 | | | | | | | |
| Ex. 5 | 1 | 12 | 34 | −15 | N,N- | 1 | — |
| | | | | | dimethyldecylamine- | | |
| | | | | | N-oxide | | |
| Ex. 6 | 1 | 12 | 34 | −15 | N,N- | 1 | PVP Mw: |
| | | | | | dimethyldecylamine- | | 8000 |
| | | | | | N-oxide | | |
| Ex. 7 | 1 | 12 | 34 | −15 | N,N- | 1 | PVP Mw: |
| | | | | | dimethyldecylamine- | | 40000 |
| | | | | | N-oxide | | |
| Ex. 8 | 1 | 12 | 34 | −15 | N,N- | 1 | Polystyrene |
| | | | | | dimethyldecylamine- | | sulfonic |
| | | | | | N-oxide | | acid Mw: |
| | | | | | | | 10000 |
| Ex. 9 | 1 | 12 | 34 | −15 | N,N- | 1 | PVP Mw: |
| | | | | | dimethyldecylamine- | | 10000 |
| | | | | | N-oxide | | |
| Ex. 10 | 1 | 12 | 34 | −15 | N,N- | 1 | Polyacrylic |
| | | | | | dimethyldecylamine- | | acid Mw: |
| | | | | | N-oxide | | 5000 |
| Ex. 11 | 1 | 12 | 34 | −15 | N,N- | 1 | — |
| | | | | | dimethyldecylamine- | | |
| | | | | | N-oxide | | |
| Comp. | 1 | 12 | 34 | −15 | — | — | — |
| Ex. 2 | | | | | | | |
| Comp. | 1 | 12 | 34 | −45 | — | — | — |
| Ex. 3 | | | | | | | |

| | | | | Polishing | | Number |
|---|---|---|---|---|---|---|
| | | | | removal | | of |
| | Defect reducing | | | rate | | defects |
| | agent | pH | Physical | Silicon | Processing | (>0.13 μm |
| | Concentration | adjuster | properties | nitride | pressure | on silicon |
| | g/L | Component | pH | [Å/min] | [psi] | nitride) |
| Ex. 1 | — | HNO₃ | 4 | 171 | 1 | 99 |
| Ex. 2 | — | HNO₃ | 2 | 250 | 1 | 92 |
| Ex. 3 | — | HNO₃ | 2 | 221 | 1 | 105 |
| Ex. 4 | | HNO₃ | 2 | 255 | 1 | 98 |
| Comp. | — | HNO₃ | 4 | 98 | 1 | 110 |
| Ex. 1 | | | | | | |
| Ex. 5 | — | HNO₃ | 2 | 215 | 1 | 76 |
| Ex. 6 | 0.01 | HNO₃ | 2 | 211 | 1 | 43 |
| Ex. 7 | 0.01 | HNO₃ | 2 | 205 | 1 | 33 |
| Ex. 8 | 0.01 | HNO₃ | 2 | 201 | 1 | 24 |
| Ex. 9 | 0.01 | HNO₃ | 2 | 213 | 1 | 44 |
| Ex. 10 | 0.01 | HNO₃ | 2 | 203 | 1 | 30 |
| Ex. 11 | — | HNO₃ | 1.5 | 310 | 1 | 145 |
| Comp. | — | HNO₃ | 2 | 122 | 1 | 236 |
| Ex. 2 | | | | | | |
| Comp. | — | HNO₃ | 2 | 154 | 1 | 331 |
| Ex. 3 | | | | | | |

In Examples 1 to 4, the anion-modified colloidal silica was used as the abrasives. In Examples 1 to 4, the concentration of the anion-modified colloidal silica in each polishing composition was set to 1 mass %. Hereinafter, mass % is indicated as wt %. In Examples 1 to 4, the anion-modified colloidal silica has the primary particle diameter of 12 nm, the secondary particle diameter of 30 nm, and the zeta potential of −45 mV.

In Examples 5 to 11, the anion-modified colloidal silica was used as the abrasives. In Examples 5 to 11, the concentration of the anion-modified colloidal silica in each polishing composition was set to 1 wt %. In Examples 5 to 11, the anion-modified colloidal silica has the primary particle diameter of 12 nm, the secondary particle diameter of 34 nm, and the zeta potential of −15 mV.

In Examples 1 to 3, N,N-dimethyldecylamine-N-oxide was used as the cationic surfactant. In Examples 1, 2, the concentration of the N,N-dimethyldecylamine-N-oxide in each polishing composition was set to 1 g/L. In Example 3, the concentration of the N,N-dimethyldecylamine-N-oxide in the polishing composition was set to 0.1 g/L.

In Example 4, N,N-dimethyldodecylamine-N-oxide was used as the cationic surfactant. In Example 4, the concentration of the N,N-dimethyldodecylamine-N-oxide in the polishing composition was set to 1 g/L.

In Examples 5 to 11, N,N-dimethyldecylamine-N-oxide was used as the cationic surfactant. In Examples 5 to 11, the concentration of the N,N-dimethyldecylamine-N-oxide in each polishing composition was set to 1 g/L.

In Example 6, polyvinylpyrrolidone (weight average molecular weight: 8000) was used as the defect reducing agent. In Example 7, polyvinylpyrrolidone (weight average molecular weight: 40000) was used as the defect reducing agent. In Example 8, polystyrene sulfonic acid (weight average molecular weight: 10000) was used as the defect reducing agent. In Example 9, polyvinyl alcohol (weight average molecular weight: 10000) was used as the defect reducing agent. In Example 10, polyacrylic acid (weight average molecular weight: 5000) was used as the defect reducing agent. In Examples 6 to 11, the concentration of the defect reducing agent in each polishing composition was set to 0.01 g/L.

In Examples 1 to 11, nitric acid (HNO₃) was used as the pH adjuster. In Example 1, the pH value of the polishing composition was adjusted to 4. In Examples 2 to 4, the pH value of each polishing composition was adjusted to 2. In Examples 5 to 10, the pH value of each polishing composition was adjusted to 2. In Example 11, the pH value of the polishing composition was adjusted to 1.5. The pH of each polishing composition (liquid temperature: 25° C.) was measured with a pH meter (product name: LAQUA (registered trademark) manufactured by HORIBA, Ltd.).

### Comparative Examples 1 to 3

The polishing compositions were prepared by the same operation as that in Examples 1 to 11, except for using components of the type and having the concentrations, for example, shown in Table 1 and adjusting the pH of each polishing composition to the value shown in Table 1.

As a difference from Examples 1 to 11, no cationic surfactants were added to the polishing compositions in Comparative Examples 1 to 3.

### Evaluation

Using the polishing compositions of Examples 1 to 11 and Comparative Examples 1 to 3, silicon wafers having a diameter of 200 mm were polished under the following polishing conditions.
Polishing device: CMP 200 mm one-side polishing device Mirra manufactured by Applied Materials
Polishing pad: Rigid polyurethane pad IC1010 manufactured by Nitta Haas Co.
Polishing pressure: 1 psi (1 psi=6894.76 Pa)
Polishing platen rotation speed: 107 rpm
Head rotation speed: 113 rpm
Supply of polishing composition: One-way
Polishing composition supply rate: 200 mL/min
Polishing time: 60 seconds

The silicon wafers subjected to the polishing are silicon wafers with a silicon nitride film. The film thickness of each silicon nitride film before the polishing and the film thickness of each silicon nitride film after the polishing were individually measured using an optical interferometry film thickness meter. Then, the polishing removal rate of each silicon nitride film was calculated from a film thickness difference and the polishing time. The polishing removal rate results are shown in Table 1.

### (Cleaning)

The polished silicon nitride substrates subjected to the polishing described above were cleaned by a cleaning method including rubbing the polished silicon nitride substrates under the following conditions while pressure was being applied on the platen used for the polishing using an acidic surfactant (MCX-SDR4, manufactured by Mitsubishi Chemical Corporation.) as a cleaning composition.

### (Cleaning Device and Cleaning Conditions)

Cleaning device: CMP 200 mm one-side polishing device Mirra manufactured by Applied Materials
Head rotation speed: 60 rpm
Platen rotation speed: 50 rpm
Cleaning pressure: 1 psi
Cleaning composition type: Acidic surfactant (MCX-SDR4 manufactured by Mitsubishi Chemical Corporation.)
Cleaning composition supply rate: 1000 mL/min Cleaning time: 60 seconds

### (Measurement of Number of Defects)

The polished wafers were measured for the number of defects of 0.13 μm or more. For the measurement of the number of defects, a wafer defect tester SP-2 manufactured by KLA TENCOR was used. The measurement was performed for a remaining portion of the polished wafer, excluding a 5 mm wide portion from an outer peripheral edge portion (0 mm to 5 mm wide portion when the outer peripheral portion was 0 mm) of the polished wafer. A smaller number of defects means that the surface scratches are fewer, the surface roughness is low, the number of residues in the surface is small, and the surface irregularities are small.

### Comparison Between Example 1, Comparative Example 1

Example 1 and Comparative Example 1 are different from each other in that the polishing composition contains or is free of the cationic surfactant. The polishing composition of Example 1 contains the cationic surfactant. The polishing composition of Comparative Example 1 is free of the cationic surfactant. The points other than the above are the same in Example 1 and Comparative Example 1. It was confirmed from Example 1, Comparative Example 1 that the addition of the cationic surfactant to the polishing composition results in an increased (enhanced) polishing removal rate of silicon nitride as compared with that in the case of not adding the cationic surfactant.

### Comparison Between Examples 1, 2

Examples 1, 2 are different from each other in the pH of the polishing composition. The pH of the polishing composition of Example 1 is 4. The pH of the polishing composition of Example 2 is 2. The points other than the above are the same in Examples 1, 2. It was confirmed from Examples 1, 2 that the polishing composition having the pH of 2 has a higher polishing removal rate of silicon nitride than that of the polishing composition having the pH of 4.

### Comparison Between Examples 2, 3

Examples 2, 3 are different from each other in the concentration of the cationic surfactant in the polishing composition. The concentration of Example 2 is 1 g/L. The concentration of Example 3 is 0.1 g/L. The points other than the above are the same in Examples 2, 3. It was confirmed from Examples 2, 3 that the polishing composition having a higher concentration of the cationic surfactant has a higher polishing removal rate of silicon nitride.

### Comparison Among Examples 2, 4, Comparative Example 1

Examples 2, 4 are different from each other in the type of the cationic surfactant. The cationic surfactant of Example 2 is N,N-dimethyldecylamine-N-oxide. The cationic surfactant of Example 4 is N,N-dimethyldodecylamine-N-oxide. The points other than the above are the same in Examples 2, 4. It was confirmed from Examples 2, 4 that, whichever of N,N-dimethyldecylamine-N-oxide or N,N-dimethyldodecylamine-N-oxide is used as the cationic surfactant, the polishing removal rate of silicon nitride is higher than that in the case (Comparative Example 1) of having the same concentration of the abrasives and not using the cationic surfactant.

### Comparison Between Example 5, Comparative Example 2

Example 5 and Comparative Example 2 are different from each other in that the polishing composition contains or is free of the cationic surfactant. The polishing composition of Example 5 contains the cationic surfactant. The polishing composition of Comparative Example 2 is free of the cationic surfactant. The points other than the above are the same in Example 5 and Comparative Example 2. It was confirmed from Example 5, Comparative Example 2 that the addition of the cationic surfactant to the polishing composition results in an increased (enhanced) polishing removal rate of silicon nitride as compared with that in the case of not adding the cationic surfactant.

### Comparison Among Examples 5, 6, 7

Examples 5, 6, 7 are different from one another in the defect reducing agent of the polishing composition. The polishing composition of Example 5 is free of the defect reducing agent. The polishing compositions of Examples 6, 7 contain 0.01 g/L of polyvinylpyrrolidone (weight average molecular weight Mw: 8000) and 0.01 g/L of polyvinylpyrrolidone (weight average molecular weight Mw: 40000), respectively, as the defect reducing agent. It was confirmed from Examples 5, 6, 7, that the polishing composition containing the defect reducing agent has fewer defects on silicon nitride.

### Comparison Between Examples 5, 8

Examples 5, 8 are different from each other in the defect reducing agent of the polishing composition. The polishing composition of Example 5 is free of the defect reducing agent. The polishing composition of Example 8 contains 0.01 g/L of polystyrene sulfonic acid (weight average molecular weight Mw: 10000) as the defect reducing agent. It was confirmed from Examples 5, 8 that the polishing composition containing the defect reducing agent has fewer defects on silicon nitride.

### Comparison Between Examples 5, 9

Examples 5, 9 are different from each other in the defect reducing agent of the polishing composition. The polishing composition of Example 5 is free of the defect reducing agent. The polishing composition of Example 9 contains 0.01 g/L of polyvinyl alcohol (weight average molecular weight Mw: 10000) as the defect reducing agent. It was confirmed from Examples 5, 9 that the polishing composition containing the defect reducing agent has fewer defects on silicon nitride.

### Comparison Between Examples 5, 10

Examples 5, 10 are different from each other in the defect reducing agent of the polishing composition. The polishing composition of Example 5 is free of the defect reducing agent. The polishing composition of Example 10 contains 0.01 g/L of polyacrylic acid (weight average molecular weight Mw: 5000) as the defect reducing agent. It was confirmed from Examples 5, 10 that the polishing composition containing the defect reducing agent has fewer defects on silicon nitride.

### Comparison Between Examples 5, 11

Examples 5, 11 are different from each other in the pH of the polishing composition. The pH of the polishing composition of Example 5 is 2. The pH of the polishing composition of Example 11 is 1.5. The points other than the above are the same in Examples 5, 11. It was confirmed from Examples 5, 11 that the polishing composition having the pH of 2 has fewer defects on silicon nitride than those of the polishing composition having the pH of 1.5.

1. A polishing composition comprising:
abrasives having a zeta potential of −5 mV or less; and
a cationic surfactant.

2. The polishing composition according to claim 1, wherein a pH is 7 or less.

3. The polishing composition according to claim 1, wherein a pH is 2 or more and 4 or less.

4. The polishing composition according to claim 1 or 2, wherein the cationic surfactant contains amine oxide.

5. The polishing composition according to claim 1, wherein the cationic surfactant contains dimethyl amine oxide.

6. The polishing composition according to claim 1, further comprising a defect reducing agent.

7. The polishing composition according to claim 1, wherein the abrasives have a secondary particle diameter (D50) of 20 nm or more and 80 nm or less.

8. The polishing composition according to claim 1, wherein the abrasives contain anion-modified silica.

9. The polishing composition according to claim 8, wherein the silica is silica having surface on which organic acid is immobilized.

10. The polishing composition according to claim 8, wherein the silica is colloidal silica.

11. The polishing composition according to claim 1,
wherein the polishing composition is used in application of polishing an object to be polished containing a silicon nitride film.

12. A polishing composition production method, the polishing composition being the polishing composition according to claim 1, the method comprising:
mixing the abrasives having the zeta potential of −5 mV or less, the cationic surfactant, and a liquid medium.

13. A polishing method comprising:
polishing an object to be polished containing silicon nitride using the polishing composition according to claim 1.

14. A semiconductor substrate production method comprising:
polishing a semiconductor substrate containing a silicon nitride film using the polishing composition according to claim 1.

15. The polishing composition according to claim 2, wherein the cationic surfactant contains amine oxide.

16. The polishing composition according to claim 2, wherein the cationic surfactant contains dimethyl amine oxide.

17. The polishing composition according to claim 2, further comprising a defect reducing agent.

18. The polishing composition according to claim 2, wherein the abrasives have a secondary particle diameter (D50) of 20 nm or more and 80 nm or less.

19. The polishing composition according to claim 2, wherein the abrasives contain anion-modified silica.

20. The polishing composition according to claim 2, wherein the polishing composition is used in application of polishing an object to be polished containing a silicon nitride film.
